(19) United States
(12) Patent Application Publication
(10) Pub. No.: US 2026/0180521 A1
(43) Pub. Date: Jun. 25, 2026

(54) Circuit having Multiple Cascode Amplifiers

(71) Applicant: TEXAS INSTRUMENTS INCORPORATED, Dallas, TX (US)

(72) Inventors: Ashlesha Yerramsetty, Hyderabad (IN); Radhika Juluri, Bangalore (IN); Meghna Agrawal, Bengaluru (IN); Debapriya Sahu, Bangalore (IN); Srinivas Veeramreddi, Bengaluru (IN); Prakhar Agrawal, Bangalore (IN)

(21) Appl. No.: 19/071,677

(22) Filed: Mar. 5, 2025

(30) Foreign Application Priority Data
Dec. 20, 2024 (IN) 202441101248

(51) Int. Cl. H03F 3/19

(52) U.S. Cl. CPC H03F 3/19; H03F 2200/451

(57) ABSTRACT

A system includes a radio frequency (RF) receiver having a low noise trans-impedance amplifier (LNTA). The LNTA is configured to receive a single-ended RF voltage signal and convert the RF voltage signal to a differential current mode signal. Further components in an RF signal chain are configured to receive the differential current mode signal. The LNTA includes cascode amplifiers.

### CROSS-REFERENCE TO RELATED APPLICATIONS

The present application claims the benefit of Indian Provisional Patent Application 202441101248, filed Dec. 20, 2024, the disclosure of which is hereby incorporated by reference in its entirety.

### TECHNICAL FIELD

The present application relates generally to electronic circuits and methods, and in particular embodiments, to a circuit having multiple cascode amplifiers.

### BACKGROUND

Radio frequency (RF) receivers are used in a variety of devices that rely on wireless communications. These RF receivers may operate at a variety of frequencies based on their applications. For example, cellular telephones, Wi-Fi devices, Bluetooth devices, and the like, operate at a variety of frequencies and may employ a RF transmitters to receive signals over the air.

### SUMMARY

In accordance to an embodiment, a circuit includes: a first cascode amplifier having a first P type transistor and a second P type transistor; a second cascode amplifier, having a first N type transistor and a second N type transistor, where a current path terminal of the second P type transistor is coupled to a current path terminal of the second N type transistor; a first capacitor coupled between a control terminal of the first N type transistor and a control terminal of the first P type transistor; a third cascode amplifier having a third P type transistor and a fourth P type transistor; and a fourth cascode amplifier having a third N type transistor and a fourth N type transistor, where a current path terminal of the fourth P type transistor is coupled to a current path terminal of the fourth N type transistor, where a control terminal of the third P type transistor is coupled to a current path terminal of the first P type transistor, and where a control terminal of the third N type transistor is coupled to a current path terminal of the first N type transistor.

In accordance to an embodiment, a device includes: a radio frequency (RF) input terminal; a low noise trans-impedance amplifier (LNTA), the LNTA including: first and second transistors, where the first transistor has a control terminal and first and second current path terminals, and where the second transistor has a control terminal and first and second current path terminals, where the control terminal of the first transistor is coupled to the RF input terminal, and where the second current path terminal of the second transistor is coupled to the first current path terminal of the first transistor; third and fourth transistors, where the third transistor has a control terminal coupled to the first current path terminal of the first transistor, and first and second current path terminal, where the fourth transistor has a control terminal, and first and second current path terminals, where the second current path terminal of the fourth transistor is coupled to the first current path terminal of the first transistor; fifth and sixth transistors, where the fifth transistor includes a control terminal and first and second current path terminals, where the sixth transistor includes a control terminal and first and second current path terminals, where the second current path terminal of the first transistor is coupled to the first current path terminal of the sixth transistor, and where the second current path terminal of the sixth transistor is coupled to the first current path terminal of the first transistor; and seventh and eighths transistors, where the seventh transistor includes a control terminal and first and second current path terminals, where the eighth transistor includes a control terminal and first and second current path terminals, where the control terminal of the seventh transistor is coupled to the second current path terminal of the fifth transistor; a first resistor coupled between the control terminal of the fifth transistor and the second current path terminal of the sixth transistor; and a second resistor coupled between the control terminal of the seventh transistor and the second current path terminal of the eighth transistor.

In accordance to an embodiment, a device includes: a radio frequency (RF) input terminal; a low noise trans-impedance amplifier (LNTA), the LNTA including: first and second transistors, where the first transistor has a control terminal and first and second current path terminals, and where the second transistor has a control terminal and first and second current path terminals, where the control terminal of the first transistor is coupled to the RF input terminal, and where the second current path terminal of the second transistor is coupled to the first current path terminal of the first transistor; third and fourth transistors, where the third transistor has a control terminal coupled to the first current path terminal of the first transistor, and first and second current path terminal, where the fourth transistor has a control terminal, and first and second current path terminals, where the second current path terminal of the fourth transistor is coupled to the first current path terminal of the first transistor; fifth and sixth transistors, where the fifth transistor includes a control terminal and first and second current path terminals, where the sixth transistor includes a control terminal and first and second current path terminals, where the second current path terminal of the first transistor is coupled to the first current path terminal of the sixth transistor, and where the second current path terminal of the sixth transistor is coupled to the first current path terminal of the first transistor; and seventh and eighths transistors, where the seventh transistor includes a control terminal and first and second current path terminals, where the eighths transistor includes a control terminal and first and second current path terminals, where the control terminal of the seventh transistor is coupled to the second current path terminal of the fifth transistor; and a transformer having a first winding coupled to the control terminal of the first transistor, and a second winding coupled to the second current path terminal of the first transistor.

In accordance to an embodiment, a low noise trans-impedance amplifier (LNTA) includes: a first cascode amplifier having a first P type transistor and a second P type transistor, where the first P type transistor has a control terminal, and first and second current path terminals, where the second P type transistor has a control terminal, and first and second current path terminals, and where the second current path terminal of the first P type transistor is coupled to the first current path terminal of the second P type transistor; a second cascode amplifier, having a first N type transistor and a second N type transistor, where the first N type transistor has a control terminal, and first and second current path terminals, where the second N type transistor has a control terminal, and first and second current path terminals, where the second current path terminal of the second P type transistor is coupled to the first current path terminal of the second N type transistor, and where second current path terminal of the second N type transistor is coupled to the first current path terminal of the first N type transistor; a third cascode amplifier having a third P type transistor and a fourth P type transistor, where the third P type transistor has a control terminal, and first and second current path terminals, where the fourth P type transistor has a control terminal, and first and second current path terminals, and where the second current path terminal of the third P type transistor is coupled to the first current path terminal of the fourth P type transistor; and a fourth cascode amplifier having a third N type transistor and a fourth N type transistor, where the third N type transistor has a control terminal, and first and second current path terminals, where the fourth N type transistor has a control terminal, and first and second current path terminals, where the second current path terminal of the fourth N type transistor is coupled to the first current path terminal of the third N type transistor, where a control terminal of the third N type transistor is coupled to the first current path terminal of the first N type transistor, where the control terminal of the third P type transistor is coupled to the second current path of the first P type transistor, where the control terminal of the third P type transistor is coupled to the second current path terminal of the fourth P type transistor, and where the control terminal of the first P type transistor is coupled to the second current path terminal of the second P type transistor.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1 is an illustration of an example system for receiving and transmitting radio frequency (RF) signals, according to some embodiments;

FIG. 2 is an illustration of an example system for receiving RF signals, according to some embodiments; and

FIG. 3 is an illustration of an an example low noise trans-impedance amplifier (LNTA), for use in the example embodiments of FIG. 1 and FIG. 2;

FIG. 4 is an illustration of an example mixer, for use in the example embodiments of FIGS. 1 and 2; and

FIG. 5 is an illustration of an example biasing circuit, for use with an example LNTA, according to some embodiments.

Corresponding numerals and symbols in different figures generally refer to corresponding parts unless otherwise indicated. The figures are drawn to clearly illustrate the relevant aspects of the preferred embodiments and are not necessarily drawn to scale.

### DETAILED DESCRIPTION

The present disclosure is described with reference to the attached figures. The figures are provided merely to illustrate the disclosure. Several aspects of the disclosure are described below with reference to example applications for illustration. It should be understood that numerous specific details, relationships, and methods are set forth to provide an understanding of the disclosure. The present disclosure is not limited by the illustrated ordering of acts or events, as some acts may occur in different orders and/or concurrently with other acts or events. Furthermore, not all illustrated acts or events are required to implement a methodology in accordance with the present disclosure.

The description below illustrates various specific details to provide an in-depth understanding of several example embodiments according to the description. The embodiments may be obtained without one or more of the specific details, or with other methods, components, materials and the like. In other cases, known structures, materials or operations are not shown or described in detail so as not to obscure the different aspects of the embodiments. References to “an embodiment” in this description indicate that a particular configuration, structure or feature described in relation to the embodiment is included in at least one embodiment. Consequently, phrases such as “in one embodiment” that may appear at different points of the present description do not necessarily refer exactly to the same embodiment. Furthermore, specific formations, structures or features may be combined in any appropriate manner in one or more embodiments.

Various embodiments provide circuits using a low noise trans-impedance amplifier (LNTA) to provide differential current mode signals based on input single-ended radio frequency (RF) signals. An example architecture for use in an LNTA, according to some embodiments, uses four cascode amplifier circuits. A first cascode amplifier circuit may include two P type metal oxide semiconductor (PMOS) transistors, where a first PMOS transistor has a source, drain, and a gate. The source of the first PMOS transistor may be coupled to a first polarity power supply (e.g., VDD), its drain may be coupled to the source of a second PMOS transistor, and its gate may be coupled to an RF input via a capacitor.

The first cascode amplifier may be coupled to a second cascode amplifier, where that second cascode amplifier is coupled to a second polarity power supply (e.g., ground). The second cascode amplifier may include two N type metal oxide semiconductor (NMOS) transistors. A first NMOS transistor has a source, gate, and a drain. The source of the first NMOS transistor may be coupled to ground, the drain may be coupled to a second NMOS transistor, and the gate may be coupled to the RF input. A second NMOS transistor of the second cascode amplifier may have its source coupled to the drain of the first NMOS transistor, and its drain coupled to the drain of the second PMOS transistor, and its gate coupled to a bias voltage.

A third cascode amplifier may be implemented similarly to the first cascode amplifier so that it has two PMOS transistors. However, the gate of the first PMOS transistor of the third cascode amplifier is coupled to the drain of the first PMOS transistor of the first cascode amplifier. A fourth cascode amplifier may be implemented similarly to the second cascode amplifier, having two NMOS transistors. In the case of the fourth cascode amplifier, the gate of the first NMOS transistor is coupled to the drain of the first NMOS transistor of the second cascode amplifier.

Further in this example, LNTA may be configured so that the first NMOS transistor of the second cascode amplifier has a polarity-shifted relationship between its drain and its gate. As noted above, the drain of the first NMOS transistor of the second cascode amplifier may be coupled to the gate of the first NMOS transistor of the fourth cascode amplifier. This results in a relationship in which a gain from gate to source is negative one. This relationship may result in the first and second cascode amplifiers providing a positive output, and the third and fourth cascode amplifiers providing a negative output. The positive and negative outputs in this example are a current mode differential output.

Various embodiments may include potential advantages versus other systems. For instance, systems using an LNA rather than an LNTA may implement a tank circuit at the output of the LNA. However, systems using the above-described example LNTA may omit the use of the tank circuit, thereby advantageously reducing, e.g., the build of materials (BOM) and semiconductor area for the system.

Furthermore, various embodiments may omit use of a transformer at the output of the LNTA. Use of a transformer at the output would generally be expected to cause gain loss. By contrast, various embodiments may advantageously avoid such a gain loss.

Additionally, various embodiments implement the LNTA having a differential output. The differential output may allow for use of a 50% duty cycle mixer. A combination of a differential output and a 50% duty cycle mixer may advantageously result in less second-order intermodulation distortion than would be expected in a system using a single-ended output and a 25% duty cycle mixer.

Also, various embodiments may use capacitive matching for the RF input to the example LNTA. By contrast, other systems may use inductive matching. Various embodiments using capacitive matching may advantageously save materials and semiconductor area versus systems using inductive matching.

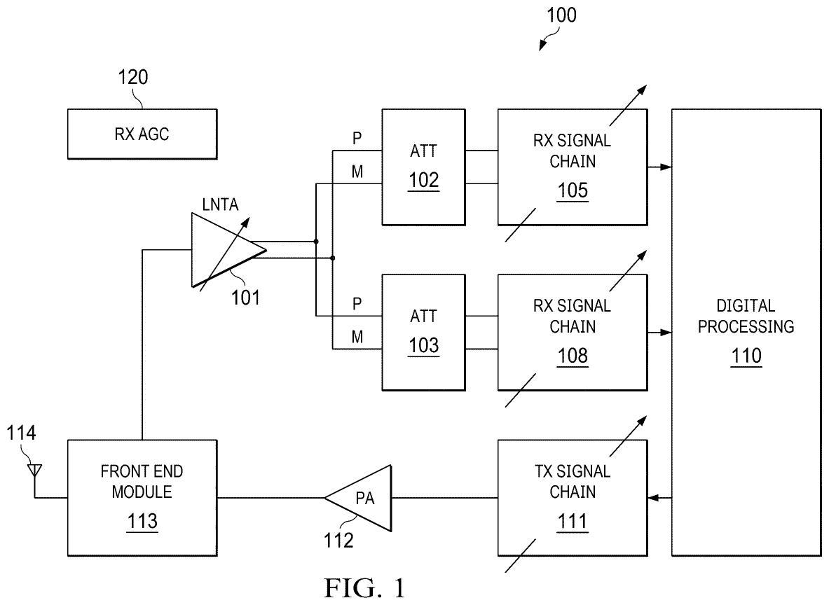

FIG. 1 is an illustration of an example system 100, according to some embodiments. In this example, system 100 may be implemented as a transceiver, which may be used for receiving and transmitting RF signals.

LNTA 101 may receive single-ended RF signals from front-end module 113 and antenna 114. For instance, the receive signal chains 105, 108, may share the front-end module 113 and the antenna 114 with the transmit signal chain 111. The front end module 113 may include, e.g., filters and switches so that antenna 114 may be used for both transmitting and receiving over the air. For instance, the front end module 113 may include switches to perform a multiplexing function over time so that at some times antenna 114 is used for reception and other times antenna 114 is used for transmission. Front end module 113 may also include filters to remove unwanted signals. However, the scope of implementations is not limited to LNTA 101 sharing antenna 114 with power amplifier 112. Rather, the scope of implementations may include power amplifier 112 having its own antenna or antenna array separate from an antenna or antenna array used for input amplifier circuit 102.

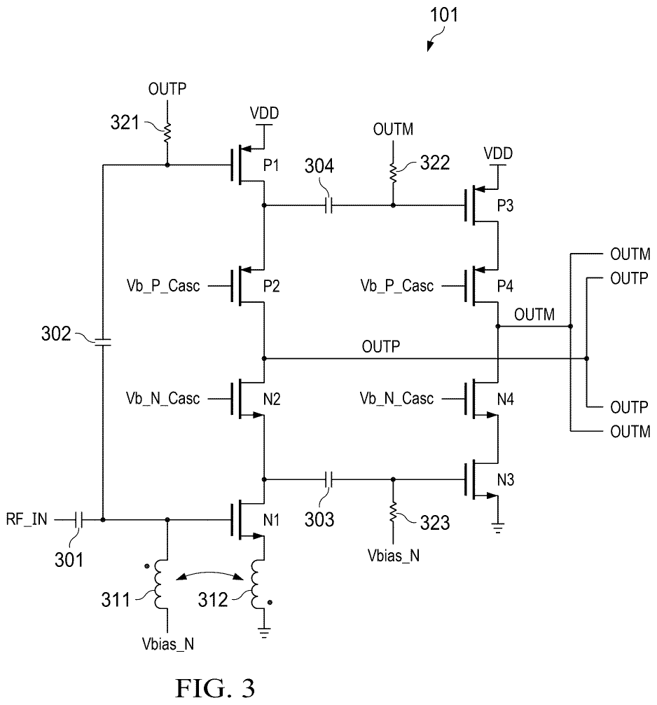

LNTA 101 includes a set of differential outputs coupled to the RX signal chain 105 and RX signal chain 108 via attenuators 102 and 103, respectively. In this example, the positive (+) conductor of the differential output is labeled with P, and the negative (−) conductor of the differential output is labeled M. Furthermore, the output of LNTA 101 is a current mode signal. An example architecture that may be used for LNTA 101 is described in more detail with respect to FIG. 3.

The attenuators 102 and 103 may be implemented in any appropriate manner. For instance, each one of attenuators 102 and 103 may be implemented as adjustable capacitive attenuator circuits, such as those described in the U.S. Patent Application, entitled, “CIRCUITS AND METHODS PROVIDING A SIGNAL PATH WITH AN ADJUSTABLE ATTENUATOR,” associated with attorney docket T105315US01, filed on even date herewith and incorporated by reference herein. Nevertheless, other attenuators, such as resistive attenuators may be used in other embodiments. Furthermore, some embodiments may dispense with attenuators 102 and 103 altogether. For example, some embodiments may use other adjustable gain components within the receive signal chains 105 and 108 for gain adjustment.

System 100 includes both receive signal chain 105 and receive signal chain 108. In one example, receive signal chain 105 is associated with an in-phase (I) signal, and receive signal chain 108 is associated with a quadrature-phase (Q) signal. Both of the RX signal chains 105 and 108 may include components that have adjustable gains. Examples of components in RX signal chains 105 and 108 may include mixers, filters, amplifiers, and/or other appropriate components. Thus, in some examples, each receive signal chain 105, 108 may include a mixer to reduce a frequency of the signal down to baseband or intermediate frequency, one or more filters and amplifiers to adjust a gain, and an analog-to-digital converter (ADC) circuit. At the output of each receive signal chain 105, 108, is a digital signal, which may be received by digital processing circuit 110. Examples of digital processing components may include one or more generic or custom processors or controllers coupled to a memory and configured to execute instructions in the memory, hardware accelerators, field programmable gate arrays (FPGAs), and other (e.g., digital) circuits, which allow for processing data and for controlling operation of system 100.

Transmit signal chain 111 is also coupled to digital processing circuit 110, and it may receive digital signals, which it may convert to analog signals to transmit as RF signals over antenna 114. For instance, the transmit signal chain 111 may include a digital to analog converter (DAC) circuit, amplifiers, filters, a mixer, and/or the like. One or multiple components within transmit signal chain 111 may include variable gain. Transmit signal chain 111 may provide an RF signal to the power amplifier 112. The power amplifier 112 may amplify the RF signal to an appropriate level for transmission over a wireless medium by antenna 114.

Receive AGC circuit 120 may control adjustable gain in any of the receive components, such as in the input amplifier circuit 102, attenuators 102 and 103, and receive signal chains 105 and 108. An example AGC algorithm, such as may be implemented by receive AGC circuit 120, is described in more detail in the U.S. Patent Application associated with attorney docket T105315US01.

System 100 may be implemented on one or more chips. Each of the chips may be implemented using semiconductor dies in semiconductor packaging. In one example, the entirety of system 100 may be implemented on a single integrated circuit (IC) chip. In another example, some parts of system 100, such as antenna 114, may be either on a separate chip or not on a chip at all. In another example, LNTA 101, PA 112, front end module 113, and antenna 114 may be implemented separately from a chip on which the receive signal chains 105 and 108, the transmit signal chain 111, and the digital processing 110 are implemented. In yet another example, system 100 may be implemented as part of a larger system on-chip, having other circuits, such as a modem, processor cores, and the like.

System 100 may be used in any appropriate application, such as in a Wi-Fi access point, a smart phone, tablet, or computer, a Bluetooth device, such as a Bluetooth low energy (BLE) device, an ultra-wideband (UWB) device, a radar device, a keyfob or card for access control, and/or the like.

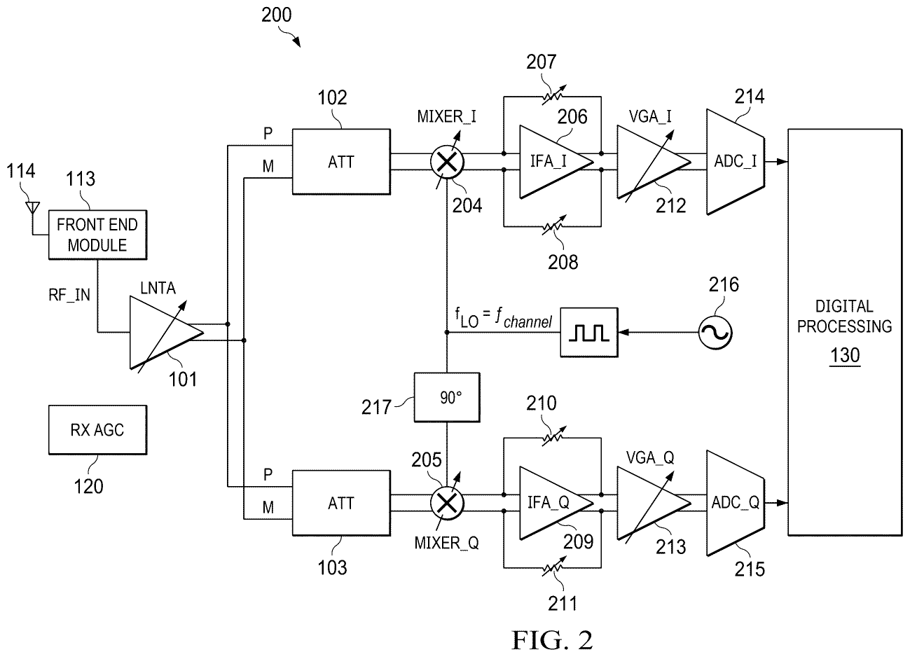

FIG. 2 is an illustration of an example system 200, for receiving wireless signals, according to some embodiments. For ease of illustration, a transmit signal chain has not been illustrated in FIG. 2, though it is understood that system 200 may be implemented with a transmit signal chain.

Example system 200 may be implemented according to the principles discussed above with respect to FIG. 1. For instance, mixer 204, amplifiers 206 and 212, and ADC 214 may correspond to receive signal chain 105. Mixer 205, amplifiers 209 and 213, and ADC 215 may correspond to receive signal chain 108.

The differential output of LNTA 101 is split so that attenuator 102 is coupled to the positive and negative output terminals of LNTA 101, as is attenuator 103. Mixer circuit 204 is coupled to the positive and negative output terminals of LNTA 101 via attenuator 103. Similarly, mixer circuit 205 is coupled to the positive and negative output terminals of LNTA 101 via attenuator 103.

Each of the mixer circuits 204, 205 are coupled to oscillator circuit 216. Oscillator circuit 216 may be implemented in any appropriate fashion, such as being implemented as a PLL or other appropriate circuit. The output of oscillator circuit 216 is split, so that the output of oscillator 216 that is received by mixer 205 is phase-shifted 90° by 90° phase shift circuit 217. By contrast, the output of oscillator 216 that is received by mixer 204 is not phase-shifted. Thus, mixer circuit 204 is implemented as in-phase, and mixer circuit 205 is implemented as quadrature-phase. Mixer circuits 204 and 205 are configured to receive the output of oscillator 216 and 90° phase shift circuit 217 at the respective clock inputs.

Each of mixer circuits 204 and 205 may include an adjustable gain. Furthermore, mixer circuits 204 and 205 may adjust a frequency of the RF signal down, such as from a gigahertz range to a megahertz range. However, the scope of implementations is not limited to any particular frequency range of operation.

In some embodiments, mixers 204 and 205 are current-mode mixers.

In some embodiments, the mixers 204 and 205 down convert their respective I and Q current mode signals to an intermediate frequency or baseband. Furthermore, in some embodiments, each of the mixers 204, 205 includes a differential current mode output.

In some embodiments, intermediate frequency amplifier (IFA) 206 receives the differential output from mixer 204 at its inputs and provides a gain adjusted differential voltage output. For instance, resistor 207 is coupled from positive input to positive output of IFA 206, and resistor 208 is coupled from negative input to negative output of IFA 206. Each of resistors 207 and 208 may be implemented to be adjustable to change a level of gain provided by IFA 206. Furthermore, IFA 206 may include an analog filter to reduce unwanted frequencies from the intermediate frequency or baseband signal.

In some embodiments, IFA 209 is implemented similarly to IFA 206. For instance, resistors 210 and 211 may be implemented similarly to resistors 207 and 208 to provide adjustable gain. Furthermore, IFA 209 may provide analog filtering to reduce unwanted frequencies from the intermediate frequency or baseband signal.

In some embodiments, variable gain amplifier (VGA) 212 receives the gain adjusted differential output of IFA 206 and provides an adjustable gain to the current mode I signal. VGA 213 receives the gain adjusted differential output of IFA 209 and provides an adjustable gain to the Q signal. VGA 212 and VGA 213 may be implemented as operational amplifiers or other appropriate amplifier circuit architecture. In some embodiments, VGA 212 generates a differential voltage output, which it provides to ADC 214. VGA 213 generates a differential voltage output, which it provides to ADC 215. ADCs 214, 215 convert the respective I and Q signals from analog to digital and provide respective digital outputs the digital processing circuit 110.

In some embodiments, receive AGC circuit 120 may control adjustable gain of the various components of system 200. For instance, receive AGC circuit 120 may provide control signals to each of the LNTA 101 adjustable capacitive attenuators 102 and 103, mixers 204 and 205, resistors 207-208, and 210-211, and VGAs 212 and 213.

FIG. 3 is an illustration of an example architecture for use in LNTA 101, according to some embodiments. In FIG. 3, the outputs OUTP and OUTM correspond to M and P of FIGS. 1 and 2 respectively.

LNTA 101 includes four different cascode amplifiers. Transistors P1 and P2 form a first cascode amplifier, with transistor P1 being a common source stage of the cascode amplifier, and transistor P2 being a common gate stage of the cascode amplifier. Transistors N1 and N2 form another cascode amplifier, with N1 being a common source stage and N2 being a common gate stage.

Transistors P3 and P4 form another cascode amplifier, with P3 being a common source stage and P4 being a common gate stage. N3 and N4 form another cascode amplifier, with N3 being a common source stage and N4 being a common gate stage. Thus, each of the four cascode amplifiers includes a common source stage and a common gate stage.

The transistors labeled P in this embodiment are P type metal oxide semiconductor (PMOS) transistors, and the transistors labeled N in this embodiment are N type metal oxide semiconductor (NMOS) transistors. However, the scope of implementation is not limited to NMOS devices, as other transistor technologies may be used as well, such as bipolar junction transistors (BJTs), and the like may be used. For instance, in a BJT arrangement, each cascode amplifier may be adapted to have a common emitter stage in a common base stage.

The cascode amplifier that includes N1 and N2 is coupled to the single-ended RF input (RF_IN) via capacitor 301. There is also a transformer coupled to the gate and source of transistor N1, where the transformer includes inductors 311 and 312, having opposite polarity windings. Inductor 311 is coupled between the gate of transistor N1 and a bias voltage (Vbias_N), and inductor 312 is coupled between the source of transistor N1 and ground. The gate of transistor N2 is coupled to another bias voltage (Vb_N_Casc), the source of transistor N2 is coupled to the drain of transistor N1, and the drain of transistor N2 is coupled to the drain of transistor P2. The drains of transistors N2 and P2 may be used as an output node for the output current OUTP.

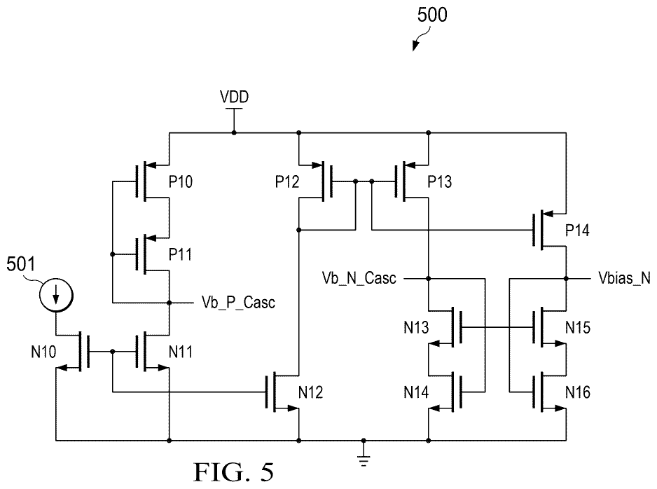

The cascode amplifier that includes transistors P1 and P2 is coupled to VDD at the source of transistor P1. The gate of transistor P1 is coupled to the RF input via capacitor 302 and capacitor 301. The gate of transistor P1 is also coupled to the drain of transistor P2 via resistor 321. The gate of transistor P2 is coupled to another bias voltage (Vb_P_Casc). The bias voltages Vbias_N, Vb_N_Casc, and Vb_P_Casc are described in more detail with respect to FIG. 5. In short, each of the bias voltages is a direct current (DC) voltage configured to cause a gate source voltage (Vgs) at its respective transistor sufficient to keep that transistor in its saturation operating region. For example, in some embodiments, each of the bias voltages is configured to keep its respective transistor in an on state during operation.

The capacitors 301 and 302 may provide input matching for the LNTA 101. Similarly, capacitors 304 and 303 may provide input matching for the structure that includes the cascode amplifier having transistors N3 and N4 and the cascode amplifier having transistors P3 and P4. Thus, in this example, input matching is performed using capacitors rather than, e.g., inductors.

The cascode amplifier that includes transistors N3 and N4 is coupled to ground by the source of transistor N3. The gate of N3 is coupled to the drain of N1 by transistor 303. The gate of N3 is also coupled to the bias voltage Vbias_N via resistor 323. The source of transistor N4 is coupled to the drain of transistor N3, and the gate of transistor N4 is coupled to the bias voltage Vb_N_Casc. The drain of N4 is coupled to the drain of P4, and those drains may be used as an output node for the output current OUTM.

The cascode amplifier that includes transistors P3 and P4 is coupled to VDD by the source of P3. The gate of P3 is coupled to the drain of P1 via capacitor 304, and the gate of P3 is also coupled to the drain of P4 via transistor 322. The gate of transistor P4 is coupled to the bias voltage Vb_P_Casc, and the source of P4 is coupled to the drain of P3.

During operation of LNTA 101, the RF input RF_IN receives a single-ended RF voltage signal, such as via antenna 114, and outputs a current mode differential signal, where the positive and negative components of the output differential signal are OUTP (positive, +) and OUTM (negative, −). The RF input RF_IN is coupled to the gate of transistor N1. As noted above, the transformer at the gate and source of N1 includes inductors 311 and 312 having opposite polarity windings, and inductor 312 couples the source of N1 to ground. Such arrangement may support the relationship between the gate and the drain of N1 to have a gain of, e.g., −1. Thus, the RF input signal (RF_IN) is inverted at the drain of N1. For example, in some embodiments, the gate of N3 is coupled to the inverse of RF_IN.

The transistor P1 is coupled to VDD and also receives the RF input signal, and the voltage at the drain of P1 has a negative gain compared to the voltage at the gate of P1. The voltage at the drain of P1 is applied to the gate of P3. Thus, the four different cascode amplifiers provide a current mode differential output signal. As noted above in FIGS. 1 and 2, the differential current mode output signal may be applied to one or more signal chains, such as an I signal chain and a Q signal chain.

The architecture shown in FIG. 3 is an example architecture that may be used for LNTA 101. Other embodiments may adapt the architecture of FIG. 3 to include gain adjustable components, such as described in the U.S. Patent Application, entitled, “CIRCUIT HAVING MULTIPLE CASCODE AMPLIFIERS AND CONTROLLABLE COMPONENTS,” associated with attorney docket T105611US01, filed on even date herewith and incorporated by reference herein.

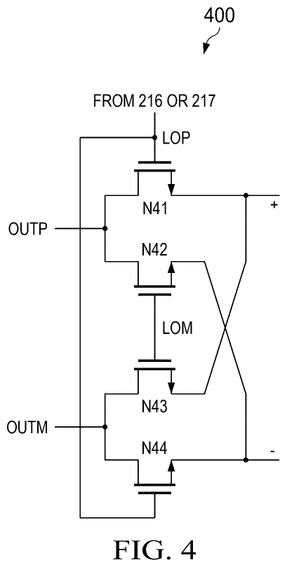

FIG. 4 is an illustration of an example mixer 400, which may be used in various implementations in a receive signal chain, according to some embodiments. For instance, the mixers 204 and 205 of FIG. 2 may be configured according to the architecture of mixer 400.

Mixer 400 is coupled to the output terminals of LNTA 101 by the drain terminals of transistors N41-44. More specifically, the drain terminals of N41-N42 are coupled to the positive component of the differential current mode signal (OUTP), and the drain terminals of N43-N44 are coupled to the negative component of the differential current mode signal (OUTM). The gates of transistors N41 and N44 are coupled to a signal from either oscillator 216 or phase shift circuit 217, depending upon whether the mixer 500 is implemented to provide an in-phase output component or a quadrature-phase output component. Thus, the signal LOP is an oscillating signal at either 0° or 90. The signal LOM is an inverted version of the LOP signal, and it is coupled to the gates of transistors N42 and N43. The + and − outputs of the mixer provide a differential current mode signal that is down converted from the differential current mode signal (OUTP and OUTM) from LNTA 101.

As noted above, mixer 400 may be configured as a 50% duty cycle mixer. In some implementations, a 50% duty cycle mixer may advantageously result in less intermodulation distortion than would be expected of a 25% duty cycle mixer of other systems.

FIG. 5 is an illustration of an example bias circuit 500, according to some embodiments. Bias circuit 500 may be used in some implementations to provide the DC bias voltages Vbias_n, Vb_P_Casc, and Vb_N_Casc discussed above with respect to FIG. 3 to provide biasing to the transistors of LNTA 101. In this example, the bias circuit 500 is static, so that during normal operation, it provides bias voltages that are stable.

Bias circuit 500 includes current source 501 coupled to a drain of transistor N10, and the source of transistor N10 is coupled to ground. The gate of transistor N10 is shorted to the gate of transistor N11 and to the gate of transistor N12.

Bias circuit 500 includes four different legs coupled between VDD and ground. A first leg includes transistors P10, P11, and N11. A second leg includes transistor P12 and N12. A third leg includes transistors P13, N13, and N14. The fourth leg includes transistors P14, N15, and N16.

Transistor P10 is coupled at its source to VDD and at its drain to the source of P11. The drain of P11 is coupled to the drain of N11, and the source of N11 is coupled to ground. The gates of P10 and P11 are shorted to each other and further shorted to the drain of P11. The drain of P11 (the drain of N11 as well) is configured as a node that provides the bias voltage Vb_P_Casc.

Transistor P12 is coupled at its source to VDD and at its drain to the drain of N12. The source of N12 is coupled to ground. The drain of N12 and the drain of P12 are coupled to the gate of P12, and the gates of P12, P13, and P14 are shorted together. Transistor P13 is coupled at its source to VDD and at its drain to the drain of N13. N13 is coupled at its source to the drain of N14, which is coupled at its source to ground. The drain of P13 and the drain of N13 is configured as a node that provides the bias voltage Vb_N_Casc. The gate of N14 is shorted to the gate of N13 and to the drain of P13.

Transistor P14 is coupled at its source to VDD and at its drain to the drain of N15. The drain of P14 and the drain of N15 are configured as a node that provides the bias voltage Vbias_N. The source of N15 is coupled to the drain of N16, the source of which is coupled to ground. The gate of N16 is coupled to the drain of N15.

Of course, the scope of implementations may include any appropriate bias circuit that may be used to provide the various bias voltages, with example bias circuit 500 being one example. Any bias circuit architecture operable to provide appropriate bias voltages may be used. As noted above, the various bias voltages are configured to maintain their respective transistors (FIG. 3) in a saturation region of operation during use of LNTA 101.

Example embodiments of the present disclosure are summarized here. Other embodiments can also be understood from the entirety of the specification and the claims filed herein.

Example 1. A circuit including: a first cascode amplifier having a first P type transistor and a second P type transistor; a second cascode amplifier, having a first N type transistor and a second N type transistor, where a current path terminal of the second P type transistor is coupled to a current path terminal of the second N type transistor; a first capacitor coupled between a control terminal of the first N type transistor and a control terminal of the first P type transistor; a third cascode amplifier having a third P type transistor and a fourth P type transistor; and a fourth cascode amplifier having a third N type transistor and a fourth N type transistor, where a current path terminal of the fourth P type transistor is coupled to a current path terminal of the fourth N type transistor, where a control terminal of the third P type transistor is coupled to a current path terminal of the first P type transistor, and where a control terminal of the third N type transistor is coupled to a current path terminal of the first N type transistor.

Example 2. The circuit of example 1, further including: a second capacitor coupled between the current path terminal of the first P type transistor and the control terminal of the third P type transistor; and a third capacitor coupled between the current path terminal of the first N type transistor and the control terminal of the third N type transistor.

Example 3. The circuit of one of examples 1 or 2, further including: a fourth capacitor having a first terminal coupled to the control terminal of the first N type transistor, and a second terminal coupled to a radio frequency (RF) input terminal.

Example 4. The circuit of one of examples 1 to 3, further including: a transformer having a first winding coupled to the control terminal of the first N type transistor, and a second winding coupled to an additional current path terminal of the first N type transistor.

Example 5. The circuit of one of examples 1 to 4, where the first winding and the second winding are windings of opposite polarity.

Example 6. The circuit of one of examples 1 to 5, where the first winding is coupled between the control terminal of the first N type transistor and a positive reference terminal, and where the second winding is coupled between the additional current path terminal of the first N type transistor and a ground terminal.

Example 7. The circuit of one of examples 1 to 6, further including a first resistor coupled between the control terminal of the third N type transistor and the positive reference terminal.

Example 8. The circuit of one of examples 1 to 7, further including: a first resistor coupled between the control terminal of the first P type transistor and the current path terminal of the second P type transistor; and a second resistor coupled between the control terminal of the third P type transistor and the current path terminal of the fourth P type transistor.

Example 9. The circuit of one of examples 1 to 8, where the first cascode amplifier, the second cascode amplifier, the third cascode amplifier, and the fourth cascode amplifier are arranged as a low noise trans-impedance amplifier (LNTA).

Example 10. The circuit of one of examples 1 to 9, further including: a bias circuit, configured to provide a first bias voltage to control terminals of the second P type transistor and the fourth P type transistor, configured to provide a second bias voltage to control terminals of the second N type transistor and the fourth N type transistor, and configured to provide a third bias voltage to a resistor coupled to the control terminal of the third N type transistor.

Example 11. The circuit of one of examples 1 to 10, further including a bias circuit including: a fifth P type transistor and a sixth P type transistor, coupled to a first power supply terminal; and a fifth N type transistor, coupled to the fifth P type transistor and coupled to a second power supply terminal, where a control terminal of the fifth P type transistor, a control terminal of the sixth P type transistor, and a current path terminal of the fifth N type transistor are shorted, and where the current path terminal of the fifth N type transistor is configured to provide a bias voltage to a control terminal of the second P type transistor and to a control terminal of the fourth P type transistor.

Example 12. The circuit of one of examples 1 to 11, further including a bias circuit including: a fifth P type transistor, coupled to a first polarity power terminal; and a fifth N type transistor and a sixth N type transistor, coupled to a second polarity power terminal, where a current path terminal of the fifth P type transistor, a control terminal of the fifth N type transistor, and a control terminal of the sixth N type transistor are shorted, further where the current path terminal of the fifth P type transistor is configured to provide a bias voltage to a control terminal of the second N type transistor and a control terminal of the fourth N type transistor.

Example 13. The circuit of one of examples 1 to 12, further including a bias circuit including: a fifth P type transistor, coupled to a first polarity power terminal; a fifth N type transistor and a sixth N type transistor, coupled to a second polarity power terminal, where a current path terminal of the fifth P type transistor and a control terminal of the fifth N type transistor are shorted, further where the current path terminal of the fifth P type transistor is configured to provide a bias voltage to a resistor coupled to the control terminal of the third N type transistor and to a terminal of an inductor coupled to the control terminal of the first N type transistor.

Example 14. The circuit of one of examples 1 to 13, where the current path terminal of the second P type transistor is coupled to a first differential input of a mixer, and where the current path terminal of the fourth P type transistor is coupled to a second differential input of the mixer.

Example 15. The circuit of one of examples 1 to 14, where the current path terminal of the second P type transistor is coupled to the first differential input of the mixer via an attenuator, and where the current path terminal of the fourth P type transistor is coupled to the second differential input of the mixer via the attenuator.

Example 16. The circuit of one of examples 1 to 15, where there is no tank circuit coupled to the first and second differential inputs of the mixer.

Example 17. The circuit of one of examples 1 to 16, where the mixer includes a 50% duty cycle mixer.

Example 18. The circuit of one of examples 1 to 17, where the mixer provides an in-phase signal path in a radio frequency (RF) receiver.

Example 19. The circuit of one of examples 1 to 18, where the mixer provides a quadrature-phase signal path in a radio frequency (RF) receiver.

Example 20. The circuit of one of examples 1 to 19, where the current path terminal of the second P type transistor corresponds to a first differential output of a low noise trans-impedance amplifier (LNTA), and where the current path terminal of the fourth P type transistor corresponds to a second differential output of the LNTA.

Example 21. The circuit of one of examples 1 to 20, where the first through fourth P type transistors are P type metal oxide semiconductor transistors, and where the first through fourth N type transistors are N type metal oxide semiconductor transistors.

Example 22. A device including: a radio frequency (RF) input terminal; a low noise trans-impedance amplifier (LNTA), the LNTA including: first and second transistors, where the first transistor has a control terminal and first and second current path terminals, and where the second transistor has a control terminal and first and second current path terminals, where the control terminal of the first transistor is coupled to the RF input terminal, and where the second current path terminal of the second transistor is coupled to the first current path terminal of the first transistor; third and fourth transistors, where the third transistor has a control terminal coupled to the first current path terminal of the first transistor, and first and second current path terminal, where the fourth transistor has a control terminal, and first and second current path terminals, where the second current path terminal of the fourth transistor is coupled to the first current path terminal of the first transistor; fifth and sixth transistors, where the fifth transistor includes a control terminal and first and second current path terminals, where the sixth transistor includes a control terminal and first and second current path terminals, where the second current path terminal of the first transistor is coupled to the first current path terminal of the sixth transistor, and where the second current path terminal of the sixth transistor is coupled to the first current path terminal of the first transistor; and seventh and eighths transistors, where the seventh transistor includes a control terminal and first and second current path terminals, where the eighth transistor includes a control terminal and first and second current path terminals, where the control terminal of the seventh transistor is coupled to the second current path terminal of the fifth transistor; a first resistor coupled between the control terminal of the fifth transistor and the second current path terminal of the sixth transistor; and a second resistor coupled between the control terminal of the seventh transistor and the second current path terminal of the eighth transistor.

Example 23. A device including: a radio frequency (RF) input terminal; a low noise trans-impedance amplifier (LNTA), the LNTA including: first and second transistors, where the first transistor has a control terminal and first and second current path terminals, and where the second transistor has a control terminal and first and second current path terminals, where the control terminal of the first transistor is coupled to the RF input terminal, and where the second current path terminal of the second transistor is coupled to the first current path terminal of the first transistor; third and fourth transistors, where the third transistor has a control terminal coupled to the first current path terminal of the first transistor, and first and second current path terminal, where the fourth transistor has a control terminal, and first and second current path terminals, where the second current path terminal of the fourth transistor is coupled to the first current path terminal of the first transistor; fifth and sixth transistors, where the fifth transistor includes a control terminal and first and second current path terminals, where the sixth transistor includes a control terminal and first and second current path terminals, where the second current path terminal of the first transistor is coupled to the first current path terminal of the sixth transistor, and where the second current path terminal of the sixth transistor is coupled to the first current path terminal of the first transistor; and seventh and eighths transistors, where the seventh transistor includes a control terminal and first and second current path terminals, where the eighths transistor includes a control terminal and first and second current path terminals, where the control terminal of the seventh transistor is coupled to the second current path terminal of the fifth transistor; and a transformer having a first winding coupled to the control terminal of the first transistor, and a second winding coupled to the second current path terminal of the first transistor.

Example 24. The device of example 23, further including a first capacitor coupled between the control terminal of the first transistor and the control terminal of the fifth transistor.

Example 25. The device of one of examples 23 or 24, further including a current mode mixer having a first input coupled to the second current path terminal of the eighth transistor, and a second input coupled to the second current path terminal of the sixth transistor.

Example 26. The device of one of examples 23 to 25, where the control terminal of the sixth transistor and the control terminal of the eighth transistor are coupled to a first output of a bias circuit.

Example 27. The device of one of examples 23 to 26, where the control terminal of the second transistor and the control terminal of the fourth transistor are coupled to a second output of the bias circuit.

Example 28. The device of one of examples 23 to 27, where the first winding of the transformer is coupled between the control terminal of the first transistor and an output of a bias circuit, and where the second winding of the transformer is coupled between the second current path terminal of the first transistor and a ground terminal.

Example 29. The device of one of examples 23 to 28, further including a resistor coupled between the output of the bias circuit and the control terminal of the third transistor.

Example 30. The device of one of examples 23 to 29, where the first, second, third, and fourth transistors are N type metal oxide semiconductor (NMOS) transistors, and where the fifth, sixth, seventh and eighth transistors are P type metal oxide semiconductor (PMOS) transistors.

Example 31. The device of one of examples 23 to 30, further including: a first capacitor coupled between the control terminal of the seventh transistor and the second current path terminal of the fifth transistor; and a second capacitor coupled between the control terminal of the third transistor and the first current path terminal of the first transistor.

Example 32. The device of one of examples 23 to 31, further including: a first resistor coupled between the control terminal of the fifth transistor and the second current path terminal of the sixth transistor; and a second resistor coupled between the control terminal of the seventh transistor and the second current path terminal of the eighth transistor. 33. The device of one of examples 23 to 31, where the device is implemented as an integrated circuit (IC).

Example 34. The device of one of examples 23 to 33, further including: a first mixer having a first differential input and a second differential input; and a second mixer having a first differential input and a second differential input, where the second current path terminal of the eighth transistor and the second current path terminal of the sixth transistor are differential coupled to the first differential input of the first mixer and are also differentially coupled to the first differential input of the second mixer.

Example 35. The device of one of examples 23 to 34, further including: a first adjustable attenuator coupled between the LNTA and the first mixer; and a second adjustable attenuator coupled between the LNTA and the second mixer.

Example 36. The device of one of examples 23 to 35, where the first mixer is configured to output an in-phase signal, and where the second mixer is configured to output a quadrature-phase signal.

Example 37. The device of one of examples 23 to 36, further including: a first intermediate frequency amplifier coupled to an output of the first mixer; a second intermediate frequency amplifier coupled to an output of the second mixer; a first variable gain amplifier coupled to an output of the first intermediate frequency amplifier; and a second variable gain amplifier coupled to an output of the second intermediate frequency amplifier.

Example 38. The device of one of examples 23 to 37, further including: an analog-to-digital converter circuit, coupled to an output of the first variable gain amplifier and coupled to an output of the second variable gain amplifier.

Example 39. The device of one of examples 23 to 38, where the analog-to-digital converter circuit includes a first analog-to-digital converter coupled to the output of the first variable gain amplifier and a second analog-to-digital converter coupled to the output of the second variable gain amplifier.

Example 40. A low noise trans-impedance amplifier (LNTA) including: a first cascode amplifier having a first P type transistor and a second P type transistor, where the first P type transistor has a control terminal, and first and second current path terminals, where the second P type transistor has a control terminal, and first and second current path terminals, and where the second current path terminal of the first P type transistor is coupled to the first current path terminal of the second P type transistor; a second cascode amplifier, having a first N type transistor and a second N type transistor, where the first N type transistor has a control terminal, and first and second current path terminals, where the second N type transistor has a control terminal, and first and second current path terminals, where the second current path terminal of the second P type transistor is coupled to the first current path terminal of the second N type transistor, and where second current path terminal of the second N type transistor is coupled to the first current path terminal of the first N type transistor; a third cascode amplifier having a third P type transistor and a fourth P type transistor, where the third P type transistor has a control terminal, and first and second current path terminals, where the fourth P type transistor has a control terminal, and first and second current path terminals, and where the second current path terminal of the third P type transistor is coupled to the first current path terminal of the fourth P type transistor; and a fourth cascode amplifier having a third N type transistor and a fourth N type transistor, where the third N type transistor has a control terminal, and first and second current path terminals, where the fourth N type transistor has a control terminal, and first and second current path terminals, where the second current path terminal of the fourth N type transistor is coupled to the first current path terminal of the third N type transistor, where a control terminal of the third N type transistor is coupled to the first current path terminal of the first N type transistor, where the control terminal of the third P type transistor is coupled to the second current path of the first P type transistor, where the control terminal of the third P type transistor is coupled to the second current path terminal of the fourth P type transistor, and where the control terminal of the first P type transistor is coupled to the second current path terminal of the second P type transistor.

Example 41. The LNTA of example 40, further including: a transformer coupled to the control terminal of the first N type transistor; and a resistor coupled to the control terminal of the third N type transistor.

Example 42. The LNTA of one of examples 40 or 41, where the transformer and the resistor are coupled to a same bias voltage terminal.

Example 43. The LNTA of one of examples 40 to 42, further including: a second capacitor coupled to the current path terminal of the first P type transistor and the control terminal of the third P type transistor; and a third capacitor coupled to the current path terminal of the first N type transistor and the control terminal of the third N type transistor.

Example 44. The LNTA of one of examples 40 to 43, further including: a first resistor coupled between the control terminal of the first P type transistor and the current path terminal of the second P type transistor; and a second resistor, coupled to the control terminal of the third P type transistor and to the second current path terminal of the fourth P type transistor.

Example 45. The LNTA of one of examples 40 to 44, where the first through fourth P type transistors are P type metal oxide semiconductor transistors, and where the first through fourth N type transistors are N type metal oxide semiconductor transistors.

Example 46. The LNTA of one of examples 40 to 45, further including: a first capacitor coupled to the control terminal of the first N type transistor and to the control terminal of the first P type transistor.

While various examples of the present disclosure have been described above, it should be understood that they have been presented by way of example only and not limitation. Numerous changes to the disclosed examples can be made in accordance with the disclosure herein without departing from the spirit or scope of the disclosure. Modifications are possible in the described embodiments, and other embodiments are possible, within the scope of the claims. Thus, the breadth and scope of the present invention should not be limited by any of the examples described above. Rather, the scope of the disclosure should be defined in accordance with the following claims and their equivalents.

What is claimed is:

1. A circuit comprising:
a first cascode amplifier having a first P type transistor and a second P type transistor;
a second cascode amplifier, having a first N type transistor and a second N type transistor, wherein a current path terminal of the second P type transistor is coupled to a current path terminal of the second N type transistor;
a first capacitor coupled between a control terminal of the first N type transistor and a control terminal of the first P type transistor;
a third cascode amplifier having a third P type transistor and a fourth P type transistor; and
a fourth cascode amplifier having a third N type transistor and a fourth N type transistor, wherein a current path terminal of the fourth P type transistor is coupled to a current path terminal of the fourth N type transistor, wherein a control terminal of the third P type transistor is coupled to a current path terminal of the first P type transistor, and wherein a control terminal of the third N type transistor is coupled to a current path terminal of the first N type transistor.

2. The circuit of claim 1, further comprising:
a second capacitor coupled between the current path terminal of the first P type transistor and the control terminal of the third P type transistor; and
a third capacitor coupled between the current path terminal of the first N type transistor and the control terminal of the third N type transistor.

3. The circuit of claim 2, further comprising:
a fourth capacitor having a first terminal coupled to the control terminal of the first N type transistor, and a second terminal coupled to a radio frequency (RF) input terminal.

4. The circuit of claim 1, further comprising:
a transformer having a first winding coupled to the control terminal of the first N type transistor, and a second winding coupled to an additional current path terminal of the first N type transistor.

5. The circuit of claim 4, wherein the first winding and the second winding are windings of opposite polarity.

6. The circuit of claim 4, wherein the first winding is coupled between the control terminal of the first N type transistor and a positive reference terminal, and wherein the second winding is coupled between the additional current path terminal of the first N type transistor and a ground terminal.

7. The circuit of claim 6, further comprising a first resistor coupled between the control terminal of the third N type transistor and the positive reference terminal.

8. The circuit of claim 1, further comprising:
a first resistor coupled between the control terminal of the first P type transistor and the current path terminal of the second P type transistor; and
a second resistor coupled between the control terminal of the third P type transistor and the current path terminal of the fourth P type transistor.

9. The circuit of claim 1, wherein the first cascode amplifier, the second cascode amplifier, the third cascode amplifier, and the fourth cascode amplifier are arranged as a low noise trans-impedance amplifier (LNTA).

10. The circuit of claim 1, further comprising:
a bias circuit, configured to provide a first bias voltage to control terminals of the second P type transistor and the fourth P type transistor, configured to provide a second bias voltage to control terminals of the second N type transistor and the fourth N type transistor, and configured to provide a third bias voltage to a resistor coupled to the control terminal of the third N type transistor.

11. The circuit of claim 1, further comprising a bias circuit comprising:
a fifth P type transistor and a sixth P type transistor, coupled to a first power supply terminal; and
a fifth N type transistor, coupled to the fifth P type transistor and coupled to a second power supply terminal, wherein a control terminal of the fifth P type transistor, a control terminal of the sixth P type transistor, and a current path terminal of the fifth N type transistor are shorted, and wherein the current path terminal of the fifth N type transistor is configured to provide a bias voltage to a control terminal of the second P type transistor and to a control terminal of the fourth P type transistor.

12. The circuit of claim 1, further comprising a bias circuit comprising:
a fifth P type transistor, coupled to a first polarity power terminal; and
a fifth N type transistor and a sixth N type transistor, coupled to a second polarity power terminal, wherein a current path terminal of the fifth P type transistor, a control terminal of the fifth N type transistor, and a control terminal of the sixth N type transistor are shorted, further wherein the current path terminal of the fifth P type transistor is configured to provide a bias voltage to a control terminal of the second N type transistor and a control terminal of the fourth N type transistor.

13. The circuit of claim 1, further comprising a bias circuit comprising:
a fifth P type transistor, coupled to a first polarity power terminal;
a fifth N type transistor and a sixth N type transistor, coupled to a second polarity power terminal, wherein a current path terminal of the fifth P type transistor and a control terminal of the fifth N type transistor are shorted, further wherein the current path terminal of the fifth P type transistor is configured to provide a bias voltage to a resistor coupled to the control terminal of the third N type transistor and to a terminal of an inductor coupled to the control terminal of the first N type transistor.

14. The circuit of claim 1, wherein the current path terminal of the second P type transistor is coupled to a first differential input of a mixer, and wherein the current path terminal of the fourth P type transistor is coupled to a second differential input of the mixer.

15. The circuit of claim 14, wherein the current path terminal of the second P type transistor is coupled to the first differential input of the mixer via an attenuator, and wherein the current path terminal of the fourth P type transistor is coupled to the second differential input of the mixer via the attenuator.

16. The circuit of claim 14, wherein there is no tank circuit coupled to the first and second differential inputs of the mixer.

17. The circuit of claim 14, wherein the mixer comprises a 50% duty cycle mixer.

18. The circuit of claim 14, wherein the mixer provides an in-phase signal path in a radio frequency (RF) receiver.

19. The circuit of claim 14, wherein the mixer provides a quadrature-phase signal path in a radio frequency (RF) receiver.

20. The circuit of claim 1, wherein the current path terminal of the second P type transistor corresponds to a first differential output of a low noise trans-impedance amplifier (LNTA), and wherein the current path terminal of the fourth P type transistor corresponds to a second differential output of the LNTA.

21. The circuit of claim 1, wherein the first through fourth P type transistors are P type metal oxide semiconductor transistors, and wherein the first through fourth N type transistors are N type metal oxide semiconductor transistors.
